(19) United States
(12) Patent Application Publication
(10) Pub. No.: US 2001/0013172 A1
(43) Pub. Date: Aug. 16, 2001

(54) Process for producing an electrical component having a plurality of soldered-on plug contacts

(76) Inventor: Klaus - Peter Wilczek, Ainring (DE)

Correspondence Address: WENDEROTH, LIND & PONACK, L.L.P., Suite 800, 2033 K Street, N.W., Washington, DC, 20006, US

(21) Appl. No.: 09/741,168

(22) Filed: Dec. 21, 2000

(30) Foreign Application Priority Data
Feb. 14, 2000 (AU) 00102944.6

(51) Int. Cl. H05K 3/00; H01R 9/00

(52) U.S. Cl. 29/884; 29/842

(57) ABSTRACT

A process for producing an electrical component having a plurality of soldered-on plug contacts projecting at a right angle, in particular a semiconductor element arranged on a ceramic board, wherein the plug contacts initially remain joined at one side by an edge strip of the sheet metal band from which they are produced, until the solder join to a substrate is made, whereupon the edge strip is removed, wherein the position of the plug contacts is established by bending the edge of the sheet metal.

The invention concerns a process for producing an electrical component having a plurality of soldered-on plug contacts projecting at a right angle, in particular a semiconductor element arranged on a ceramic board, wherein the plug contacts initially remain joined at one side by an edge strip of the sheet metal band from which they are produced, until the solder join to a substrate is made, whereupon the edge strip is removed.

At the present time electromechanical switches are used in large numbers in particular in automobile engineering. The use of electronic components instead of such relays is an obvious option to adopt by virtue of the high level of operational efficiency and the lower level of susceptibility to trouble. The inexpensive production of such electronic switches however still involves a series of problems. One of those is that the electrical connections must be afforded by plug contacts of precisely defined shape and arrangement.

When an electronic switching element is constructed in a hybrid fashion from a printed ceramic plate or board with power transistors fitted thereto, it is extremely difficult to solder on the standard plug contacts in such a way that the four conductive surfaces are coplanar and the plug pattern configuration remains within the tolerance range. To resolve that problem, it is possible to thread the plug contacts into a graphite mold which holds the plugs in position in the soldering procedure. That operation however can scarcely be automated and is therefore highly expensive. It would also be possible to inject around the plugs a holding frame of plastic material, which remains in the system. Apart from the costs involved, this involves problems in regard to subsequently casting the injection moldings in terms of material compatibility.

The invention resolves the problem of fitting the plug contacts in positionally correct relationship by providing that the position of the plug contacts is established by bending the sheet metal edge.

The degree of precision achieved is particularly high if the ends of the edge strip are connected together by a detent or latching connection. The same effect is achieved if the plug contacts additionally remain connected, until the end of the soldering operation, by a web or bar which extends at a spacing from their angled ends and which is preferably produced together with the plug contacts, while a particularly stable embodiment provides that the ends of the bar are connected together by a detent or latching connection.

Further details of the invention are described by way of example hereinafter with reference to the drawing in which:

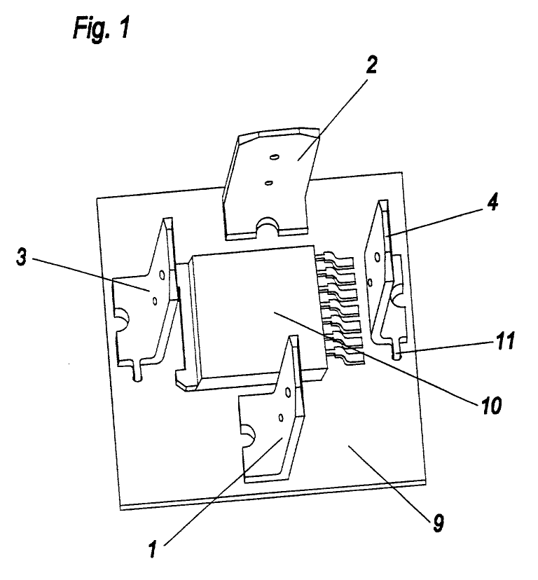

FIG. 1 diagrammatically shows the essential parts of the component to be produced,

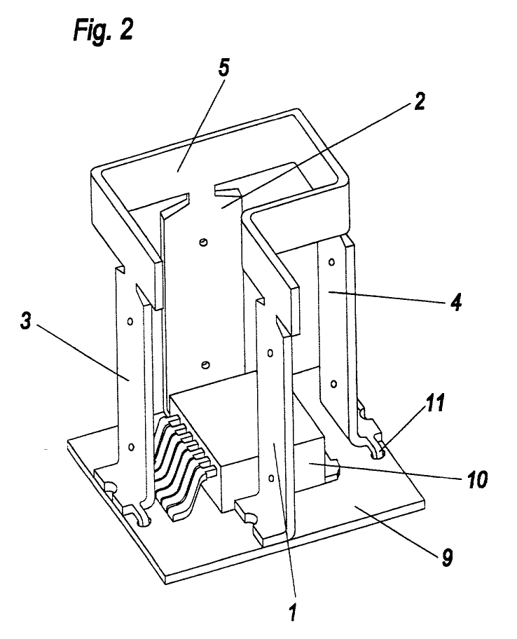

FIG. 2 shows a simple example for carrying out the process according to the invention,

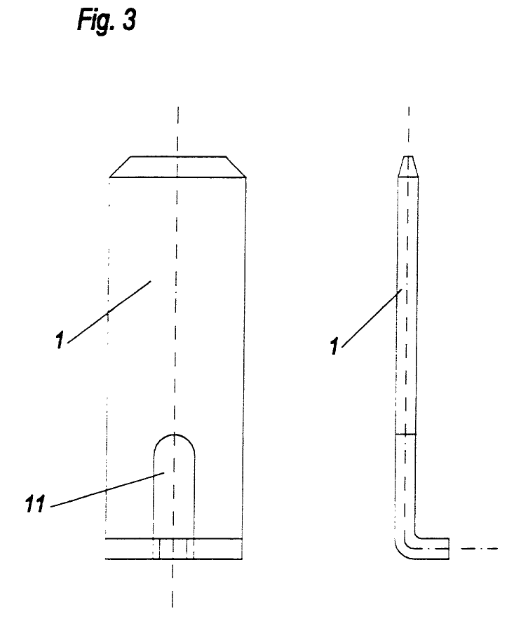

FIG. 3 is a view, close to a practical structure, of a flat plug member to be fitted,

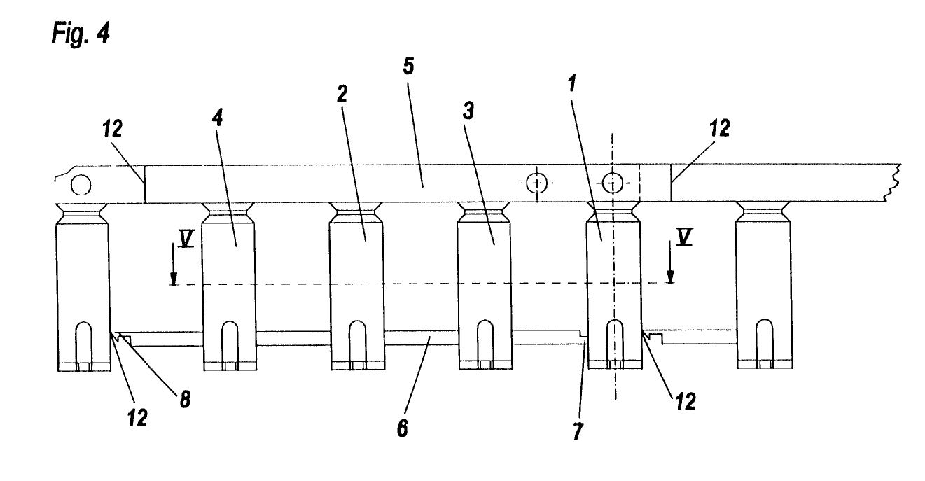

FIG. 4 shows the production of a plurality of plug members as shown in FIG. 3 from a sheet metal band, and

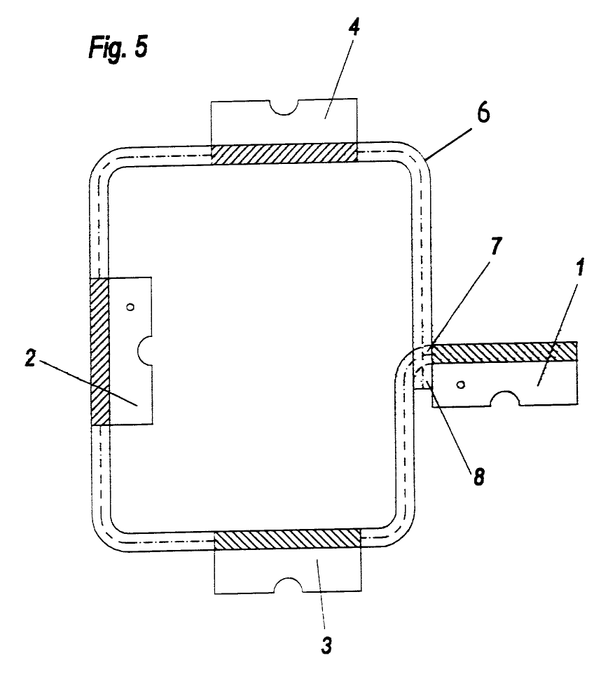

FIG. 5 is a view in section taken along line V-V in FIG. 4.

The electronic component to be produced in accordance with the invention comprises a support or substrate 9 in the form of a ceramic board, on which a circuit is printed on one side and on which a transistor element 10 is arranged on the other side. Plug contacts in the form of standardised flat plug members 1-4 of sheet metal are to be soldered precisely on to the substrate 9. For that purpose it is provided in accordance with the invention that the flat plug members 1-4 are stamped out of a sheet metal band of which, during the soldering operation, there still remains an edge strip 5 which connects the flat plug members 1-4 and in so doing holds them in their relative positions. Positioning relative to the substrate 9 can be ensured by adjustment lugs 11 which engage into corresponding openings in the substrate 9. That situation is shown in FIG. 2. After the soldering operation the edge strip 5 is removed resulting in the situation shown in FIG. 1 which illustrates the finished component. The component can however still be covered with a casting material from which the ends of the flat plug members 1-4 project.

The production process described in diagrammatic form hitherto is shown in FIGS. 3-5 in a form which is somewhat closer to practice. Thus, FIG. 3 shows that the flat plug member 1 which is angled at its lower end has a slot 11 which improves its hold in the casting material which is not shown in FIG. 1. FIG. 4 shows how flat plug members 1-4 are continuously produced from a sheet metal band by stamping and bending. After the sheet metal band has been cut to length along the cut lines 12 the subsequently free ends of the flat plug members 1-4 remain connected by an edge strip 5. A web or bar 6 offers an additional connection. The end 7 of the bar 6 initially remains connected to the flat plug member 1 and is in the form of a latching or detent catch. The free end 8 of the bar 6 forms a latching or detent projection.

FIG. 5 shows how, in the soldering procedure, the bar 6 forms a peripherally closed band around the plug members 1-4 as its ends 7, 8 are connected together, which is not possible in the case of the edge strip 5 as the flat plug member 1 extends at a right angle to the flat plug member 2 (see FIGS. 1 and 2). It will be appreciated that, after the operation of soldering the flat plug members 1-4 to the substrate 9, the bar 6 also has to be removed at least to such an extent that the electrical connection as between the flat plug members 1-4 is interrupted. That removal procedure is advantageously effected in a unitary stamping operation together with removal of the edge strip 5.

Numerous modifications may be implemented in comparison with the illustrated embodiment, without departing from the scope of the invention.

Usually the plug contacts are produced in an endless process by stamping, laser beam or water jet from a sheet metal band. The number and spacing of the plug contacts can be adapted in that respect at any time to the desired purpose of use. In particular the shape of the plug contacts is not limited to the illustrated flat plug members; it would be equally well possible to implement a rectangular cross-section for the contact pins.

1. A process for producing an electrical component having a plurality of soldered-on plug contacts projecting at a right angle, in particular a semiconductor element arranged on a ceramic board, wherein the plug contacts initially remain joined at one side by an edge strip of the sheet metal band from which they are produced, until the solder join to a substrate is made, whereupon the edge strip is removed, characterised in that the position of the plug contacts (1-4) is established by bending the edge of the sheet metal.

2. A process as set forth in claim 1 characterised in that the ends of the edge strip are connected together by a latching connection.

3. A process as set forth in claim 1 characterised in that the plug contacts (1-4) additionally remain connected until after the end of the soldering operation by a bar (6) which extends at a spacing from their angled ends (9) and which is preferably produced together with the plug contacts (1-4).

4. A process as set forth in claim 3 characterised in that the ends of the bar (6) are connected together by a latching connection (7, 8).

5. A process as set forth in claim 1 characterised in that the plug contacts (1-4) are produced in an endless process by stamping, laser beam or water jet from the sheet metal band.

6. A process as set forth in claim 3 characterised in that the edge strip (5) and the bar (6) are removed in a common stamping operation.

7. A process as set forth in claim 6 characterised in that the bar (6) is only partially cut away.

8. A process as set forth in claim 1 characterised in that the cross-section of the plug contacts (1-4) is rectangular or square.

9. A process as set forth in claim 1 characterised in that one or more of the plug contacts (1-4) have adjustment lugs (11) which can be fitted into holes in the substrate (9).
